(19) United States
(12) Patent Application Publication
(10) Pub. No.: US 2007/0024328 A1
(43) Pub. Date: Feb. 1, 2007

(54) Output driver with maintained slew rate

(76) Inventor: Soon-Kyun Shin, Seongnam-Si (KR)

Correspondence Address: LAW OFFICE OF MONICA H CHOI, P O BOX 3424, DUBLIN, OH, 430160204, US

(21) Appl. No.: 11/483,118

(22) Filed: Jul. 7, 2006

(30) Foreign Application Priority Data
Aug. 1, 2005 (KR) 2005-70345

(51) Int. Cl. H03B 1/00

(52) U.S. Cl. 327/112

(57) ABSTRACT

An output driver includes a pre-driver that generates first and second gate control signals at first and second nodes. The output driver also includes a main driver that generates an output signal from the first and second gate control signals. The pre-driver includes a capacitor and switches that turn on to forms capacitive current paths between the output node and the first and second nodes during transitions of the output signal for maintaining a slew rate of the output signal.

### BACKGROUND OF THE INVENTION

This application claims priority to Korean Patent Application No. 2005-70345, filed on Aug. 1, 2005 in the Korean Intellectual Property Office, the disclosure of which is incorporated herein in its entirety by reference.

1. Field of the Invention

The present invention relates generally to output drivers, and more particularly, to forming capacitive current paths in an output driver for maintaining slew rate.

2. Description of the Related Art

An input/output (I/O) circuit of a semiconductor integrated circuit (IC) is preferably operated at high speed, with minimal noise such as from ringing, reflections in a transmission line, etc. For reducing the noise of the I/O circuit, a transition time of a signal transmitted in the I/O circuit is increased within a range permitted by specifications. Also for meeting setup and hold time margins, a slew rate of a signal transmitted in the I/O circuit is desired to be maintained at a constant value despite variations in process, voltage, and temperature.

FIG. 1 shows a circuit diagram of a conventional output driver of a semiconductor IC. Referring to FIG. 1, the output driver includes a tri-state control logic 10, a pre-driver 30, and a main driver 40. The pre-driver 30 generates gate control signals from a data signal DATA, and the main driver 40 generates an output signal DOUT in response to the gate control signals from the pre-driver 30.

In the output driver of FIG. 1, the pre-driver 30 has metal-oxide semiconductor (MOS) transistors forming a current-mirror configuration, and a respective transmission gate is coupled to each drain of the transistors. Because respective output currents of the MOS transistors have different transition times, the output signal DOUT, i.e., the output signal of the main driver 40 may maintain a constant slew rate.

However, in the output driver of FIG. 1, on-resistances of the MOS transistors or the transmission delay time of a signal may fluctuate severely with variations of process, voltage, and temperature. Thus, the transition time and the slew rate of the output signal DOUT may fluctuate with such variations of process, voltage, and temperature.

Therefore, an output driver generating an output signal with a maintained slew rate despite variations in process, voltage, and temperature is desired.

U.S. Pat. No. 6,606,271 to Hunt discloses a circuit having a controllable slew rate by forming an integrator with a capacitor and a resistor. However, such a resistor in an integrated circuit may undesirably occupy a large area.

### SUMMARY OF THE INVENTION

Accordingly, an output driver of embodiments of the present invention includes capacitive current paths for maintaining the slew rate despite variations in process, voltage, and temperature.

An output driver according to an aspect of the present invention includes a pre-driver and a main driver. The pre-driver generates first and second gate control signals at first and second nodes, respectively, from input signals. The main driver generates an output signal at an output node from the first and second gate control signals. The pre-driver includes a capacitor coupled to the output node and switches. Each of the switches turns on to form a respective capacitive current path between the output node through the capacitor and one of the first and second nodes during a transition of the output signal.

The pre-driver in an example embodiment of the present invention includes a first switch and a second switch. The first switch turns on to form a first capacitive current path from the output node through the capacitor to the first node during a rising transition of the output signal. The second switch turns on to form a second capacitive current path from the second node through the capacitor to the output node during a falling transition of the output signal.

The first capacitive current path reduces a descending slope of the first gate control signal during the rising transition of the output signal. The second capacitive current path reduces an ascending slope of the second gate control signal during the falling transition of the output signal.

The output driver in a further embodiment of the present invention includes a tri-state control circuit that generates first and second input signals each having a respective logic state such that the output node has a high impedance when a tri-state control signal is enabled. Alternatively, the tri-state control circuit is configured to generate the first and second input signals each having a logic state depending on a data signal when the tri-state control signal is disabled.

The pre-driver in another embodiment of the present invention includes a first buffer for buffering the first input signal to generate the first gate control signal at the first node. The pre-driver also includes a second buffer for buffering the second input signal to generate the second gate control signal at the second node.

In an example embodiment of the present invention, each of the first and second buffers includes a respective inverter for inputting the first or second input signal and outputting the first or second gate control signal, and includes a respective current mirror for biasing the respective inverter.

In another embodiment of the present invention, the first switch is a first transmission gate that is turned on by the first input signal to couple the capacitor to the first node during the rising transition of the output signal. Similarly, the second switch is a second transmission gate that is turned on by the second input signal to couple the capacitor to the second node during the falling transition of the output signal.

The output driver according to another embodiment of the present invention further includes another pre-driver and another main driver. The other pre-driver generates third and fourth gate control signals at third and fourth nodes, respectively, from inversions of the input signals. The other main driver generates another output signal at another output node from the third and fourth gate control signals, and the other output signal is a complement of the output signal. The other pre-driver includes another capacitor coupled to the other output node and additional switches. Each additional switch turns on to form a respective capacitive current path between the other output node through the other capacitor and one of the third and fourth nodes during a transition of the other output signal.

For example, the other pre-driver includes a third switch and a fourth switch. The third switch turns on to form a third capacitive current path from the other output node through the other capacitor to the third node during a rising transition of the other output signal. The fourth switch turns on to form a fourth capacitive current path from the fourth node through the other capacitor to the other output node during a falling transition of the other output signal.

In that case, the third capacitive current path reduces a descending slope of the third gate control signal during the rising transition of the other output signal. The fourth capacitive current path reduces an ascending slope of the fourth gate control signal during the falling transition of the other output signal.

In this manner, the capacitive current paths reduce the descending and ascending slopes of the gate control signals used by the main driver for generating the output signal. Such reduced slopes of the gate control signals maintain the slew rate of the output signal to be more constant despite variations in process, voltage, and temperature.

### BRIEF DESCRIPTION OF THE DRAWINGS

The above and other features and advantages of the present invention will become more apparent when described in detailed exemplary embodiments thereof with reference to the attached drawings in which:

FIG. 1 shows a circuit diagram of a conventional output driver of a semiconductor integrated circuit (IC);

FIG. 2 shows a block diagram of an output driver of a semiconductor IC, according to an example embodiment of the present invention;

FIG. 3 shows a circuit diagram of a bias current generating circuit of FIG. 2, according to an example embodiment of the present invention;

FIG. 4 shows a circuit diagram of a tri-state control circuit of FIG. 2, according to an example embodiment of the present invention;

FIG. 5 shows a circuit diagram of a pre-driver and a main driver of FIG. 2, according to an example embodiment of the present invention;

FIG. 6 shows a block diagram of an output driver of a semiconductor IC for generating complementary output signals, according to another example embodiment of the present invention;

FIG. 7 is a circuit diagram of a tri-state control circuit of FIG. 6, according to an example embodiment of the present invention;

FIGS. 8A and 8B are simulation diagrams illustrating voltage waveforms at nodes of the output drivers of FIG. 2 or 6;

FIGS. 9A, 9B, and 9C are diagrams illustrating output waveforms of the conventional output driver of FIG. 1; and

FIGS. 10A, 10B, and 10C are diagrams illustrating output waveforms of the output driver of FIG. 6.

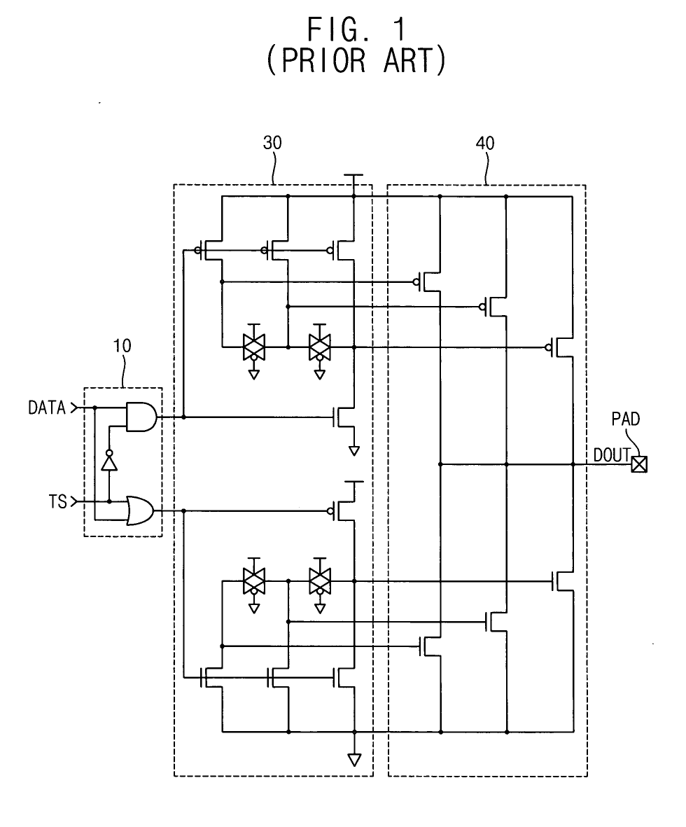

The figures referred to herein are drawn for clarity of illustration and are not necessarily drawn to scale. Elements having the same reference number in FIGS. 1, 2, 3, 4, 5, 6, 7, 8A, 8B, 9A, 9B, 9C, 1A, 10B, and 10C refer to elements having similar structure and/or function.

### DETAILED DESCRIPTION OF THE INVENTION

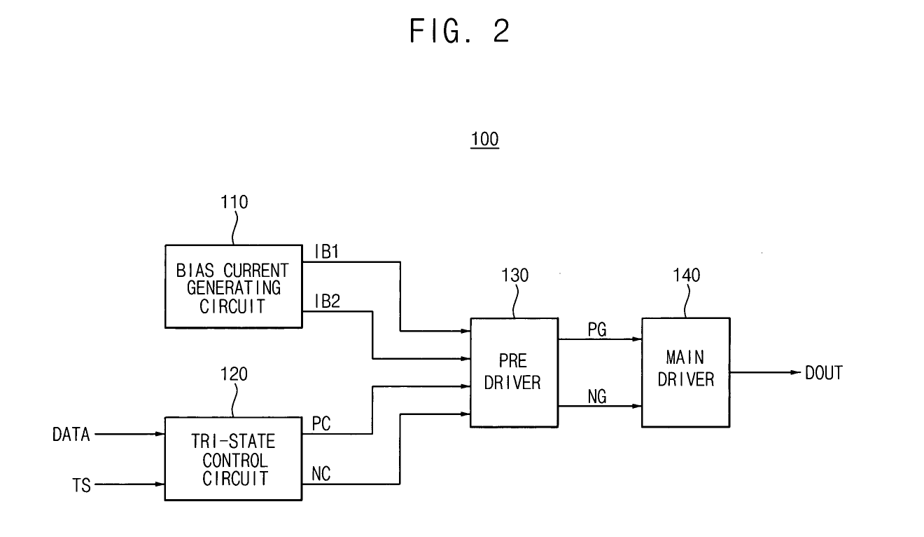

FIG. 2 shows a block diagram of an output driver 100 of a semiconductor integrated circuit (IC) according to an example embodiment of the present invention. The output driver 100 includes a bias current generating circuit 110, a tri-state control circuit 120, a pre-driver 130, and a main driver 140.

The bias current generating circuit 110 generates a first bias current IB1 and a second bias current IB2 that are provided to the pre-driver 130. The tri-state control circuit 120 generates a first input signal PC and a second input signal NC in response to a tri-state control signal TS and an input data signal DATA. The pre-driver 130 buffers the first input signal PC to generate a first gate control signal PG, and buffers the second input signal NC to generate a second gate control signal NG. The main driver 140 generates an output signal DOUT in response to the first and second gate control signals PG and NG.

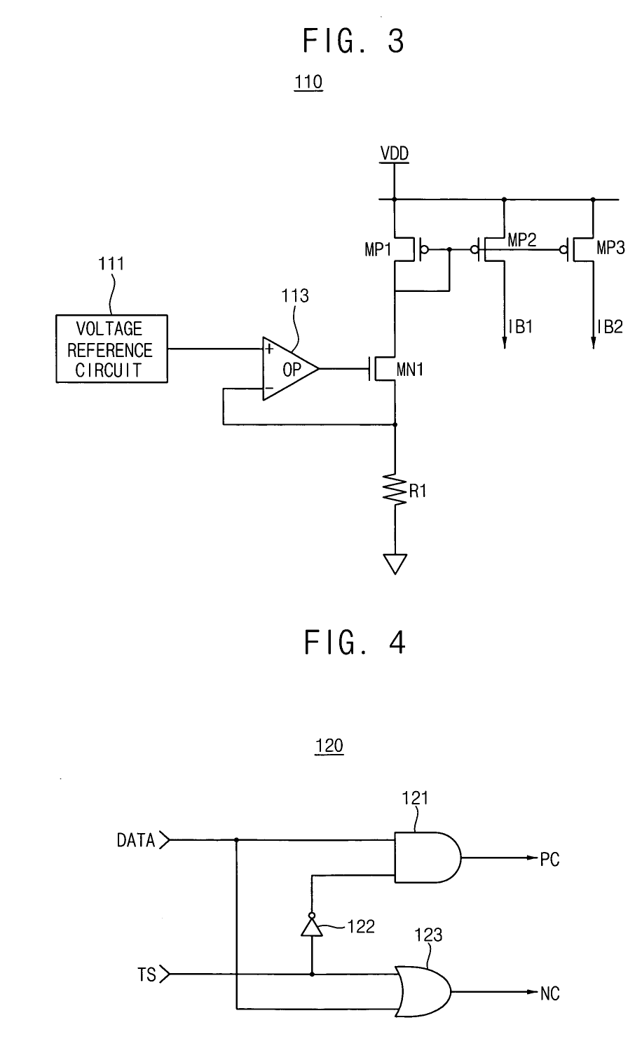

FIG. 3 shows a circuit diagram of the bias current generating circuit 110 of FIG. 2 according to an example embodiment of the present invention. The bias current generating circuit 110 includes a voltage reference circuit 111, an operational amplifier (OP-AMP) 113, an N-channel metal-oxide semiconductor (NMOS) transistor MN1, a resistor R1, and P-channel metal-oxide semiconductor (PMOS) transistors MP1, MP2, and MP3.

The voltage reference circuit 111 generates a reference voltage VREF and may be implemented as a band-gap reference voltage generating circuit. A reference current of VREF/R1 is generated through the transistors MN1 and MP1. The PMOS transistors MP1, MP2, and MP3 form a current-mirror for generating the first bias current IB1 and the second bias current IB2 from the reference current VREF/R1.

FIG. 4 is a circuit diagram of the tri-state control circuit 120 of FIG. 2 according to an example embodiment of the present invention. Referring to FIG. 4, the tri-state control circuit 120 includes an AND gate 121, an inverter 122, and an OR gate 123. The tri-state control circuit 120 inputs the data signal DATA and the tri-state control signal TS.

The inverter 122 inverts the tri-state control signal TS. The AND gate 121 performs an AND operation on the data signal DATA and the output of the inverter 122 to generate the first input signal PC. The OR gate 123 performs an OR operation on the data signal DATA and the tri-state control signal TS to generate the second input signal NC.

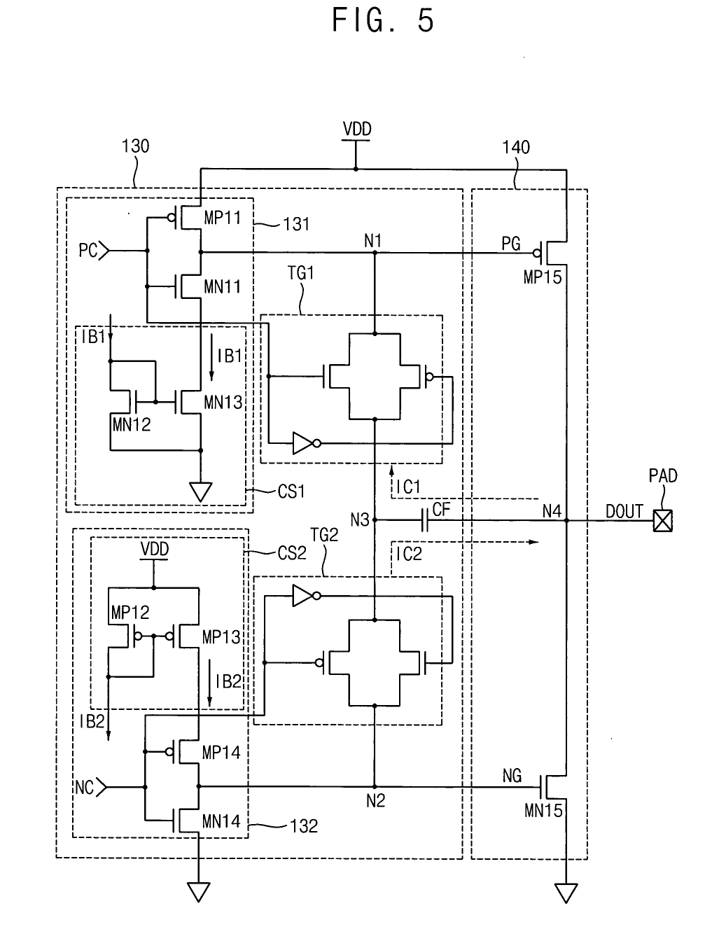

FIG. 5 is a circuit diagram of the pre-driver 130 and the main driver 140 of FIG. 2, according to an example embodiment of the present invention. The pre-driver 130 includes a first buffer 131, a second buffer 132, a first transmission gate TG1, a second transmission gate TG2, and a capacitor CF.

The first buffer 131 is biased with the first bias current IB1, and buffers the first input signal PC to generate the first gate control signal PG at a first node N1. The second buffer 132 is biased with the second bias current IB2, and buffers the second input signal NC to generate the second gate control signal NG at a second node N2.

The first transmission gate TG1 couples the first node N1 to a capacitor node N3 in response to the first input signal PC. The second transmission gate TG2 couples the second node N2 to the capacitor node N3 in response to the second input signal NC. The capacitor CF is coupled between the capacitor node N3 and an output node N4.

The main driver 140 includes a pull-up PMOS transistor MP15 and a pull-down NMOS transistor MN15. The pull-up transistor MP15 when turned on by the first gate control signal PG pulls up a voltage of the output node N4 to a high power supply voltage VDD. The pull-down transistor MN15 when turned on by the second gate control signal NG pulls down the voltage of the output node N4 to a low power supply voltage such as a ground voltage. Because the pull-up and pull-down transistors MP15 and MN15 drive an output load, such transistors MP15 and MN15 may each have bigger size than transistors MP11, MN11, MP14 and MN14 in the pre-driver 130.

The first buffer 131 includes a PMOS transistor MP11, an NMOS transistor MN11, and a current source CS1. The PMOS transistor MP11 has a source coupled to the high power supply voltage VDD, a gate applied with the first input signal PC, and a drain coupled to the first node N1. The NMOS transistor MN11 has a drain coupled to the first node N1, a gate applied with the first input signal PC, and a source coupled to the current source CS1.

The current source CS1 is configured with NMOS transistors MN12 and MN13 forming a current-mirror. The current source CS1 receives the first bias current IB1 from the bias current generating circuit 110 of FIG. 2, and biases the transistors MN11 and MP11 with the first bias current IB1.

The second buffer 132 includes a PMOS transistor MP14, an NMOS transistor MN14, and a current source CS2. The PMOS transistor MP14 has a gate applied with the second input signal NC, a drain coupled to the second node N2, and a source coupled to the current source CS2. The NMOS transistor MN14 has a drain coupled to the second node N2, a gate applied with the second input signal NC, and a source coupled to the ground voltage.

The current source CS2 is configured with PMOS transistors MP12 and MP13 forming a current-mirror. The current source CS2 receives the second bias current IB2 from the bias current generating circuit 110 of FIG. 2, and biases the transistors MP14 and MN14 with the second bias current IB2.

The operation of the output driver 100 according to an example embodiment of the present invention is now described with reference to FIGS. 2, 3, 4, and 5.

Generally, during a rising transition of the output signal DOUT, a first capacitive current path is formed from the output node N4, through the capacitor CF, and to the first node N1. Such a first capacitive current path reduces a descending slope of the first gate control signal PG for maintaining the slew rate of the output signal DOUT.

Alternatively during a falling transition of the output signal DOUT, a second capacitive current path is formed from the second node N2, through the capacitor CF, and to the output node N4. Such a second capacitive current path reduces an ascending slope of the second gate control signal NG for maintaining the slew rate of the output signal DOUT.

An operation of the tri-state control circuit 120 of FIG. 4 is now described. When the tri-state control signal TS is enabled with a logic high state, the first input signal PC is set to the logic low state, and the second input signal NC is set to the logic high state, regardless of the data signal DATA.

Such logic states of the first and second input signals PC and NC cause the output node N4 of the output driver 100 to have high impedance because the pull-up and pull-down transistors MP15 and MN15 are both turned off. Thus, the output driver 100 is in a high impedance state when the tri-state control signal TS is enabled.

Alternatively, when the tri-state control signal TS is disabled to a logic low state, both the first and second input signals PC and NC have the same logic state as the data signal DATA. Such first and second input signals PC and NC from the tri-state control circuit 120 are input by the pre-driver 130.

The PMOS transistor MP11 and the NMOS transistor MN11 form an inverter that inverts the first input signal PC to generate the first gate control signal PG at the first node N1. The PMOS transistor MP14 and the NMOS transistor MN14 form an inverter that inverts the second input signal NC to generate the second gate control signal NG at the second node N2.

First, the operation of the output driver 100 when the data signal DATA transitions from a logic low state to a logic high state (i.e., for a rising transition of the output signal DOUT) is now described. When the data signal DATA makes such a rising transition, the first and second input signals PC and NC also transition from the logic low state to the logic high state.

Initially, when the first and second input signals PC and NC are in the logic low state, both the nodes N1 and N2 are in the logic high state, and the output signal DOUT is in the logic low state. Subsequently, when the first and second input signals PC and NC transition from the logic low state to the logic high state, the first transmission gate TG1 is turned on and the second transmission gate TG2 is turned off.

In addition, the pull-up transistor MP15 is turned on and the pull-down transistor MN15 is turned off such that the output signal DOUT transitions from the logic low state to the logic high state. During such a rising transition of DOUT, a first capacitive current IC1 flows from the output node N4, through the capacitor CF and the first transmission gate TG1, to the first node N1. The capacitor CF maintains a gate-to-source voltage Vgs of the pull-up transistor MP15 such that the slew rate of the output signal DOUT reaches a targeted value during the rising transition of the output signal DOUT.

Assuming that IC1 represents the first capacitive current flowing through the capacitor CF and v represents a voltage between the output node N4 and the gate of the pull-up transistor MP15, the first capacitive current is represented as IC1=CF×dv/dt. When the level of the first capacitive current IC1 is equal to the level of the first bias current IB1, the first gate control signal PG at the gate of the pull-up transistor MP15 is changed for a predetermined time period until the first gate control signal PG reaches the ground voltage. When the first gate control signal PG at the node N1 reaches the ground voltage, the pull-up transistor MP15 is fully turned on.

In addition, as illustrated in FIG. 8B, the first capacitive current IC1 causes a reduced descending slope PG1 of the first gate control signal PG during the rising transition of the output signal DOUT. FIG. 8B illustrates the reduced descending slope PG1 contrasted with a steep fall of the first gate control signal PG. Such a more graduated slope PG1 of the first gate control signal PG results in a more constant slew rate of the output signal DOUT during the rising transition of the output signal DOUT.

The operation of the output driver 100 when the data signal DATA transitions from the logic high state to the logic low state (i.e., for a falling transition of the output signal DOUT) is now described. When the data signal DATA transitions from the logic high state to the logic low state, the first and second input signals PC and NC transition from the logic high state to the logic low state.

Initially when the first and second input signals PC and NC are in the logic high state, both the nodes N1 and N2 are in the logic low state, and the output signal DOUT is in the logic high state. Subsequently when the first and second input signals PC and NC transition from the logic high state to the logic low state, the first transmission gate TG1 is turned off and the second transmission gate TG2 is turned on.

In addition, the pull-up transistor MP15 is turned off and the pull-down transistor MN15 is turned on such that the output signal DOUT transitions from the logic high state to the logic low state. During such a falling transition of the output signal DOUT, a second capacitive current IC2 flows from the second node N2, through the second transmission gate TG2 and the capacitor CF, and to the output node N4. The second capacitive current IC2 flows until the second gate control voltage NG at the second node N2 reaches the high power supply voltage VDD such that the pull-down transistor MN15 is fully turned on.

As illustrated in FIG. 8B, the second capacitive current IC2 causes a reduced ascending slope NG1 of the second gate control signal NG during the falling transition of the output signal DOUT. FIG. 8B illustrates the reduced ascending slope NG1 contrasted with a steep rise of the second gate control signal NG. Such a more graduated slope NG1 of the second gate control signal NG results in a more constant slew rate of the output signal DOUT during the falling transition of the output signal DOUT.

The transmission gates TG1 and TG2 in the output driver 100 of FIG. 5 may be replaced with other elements having a switching function.

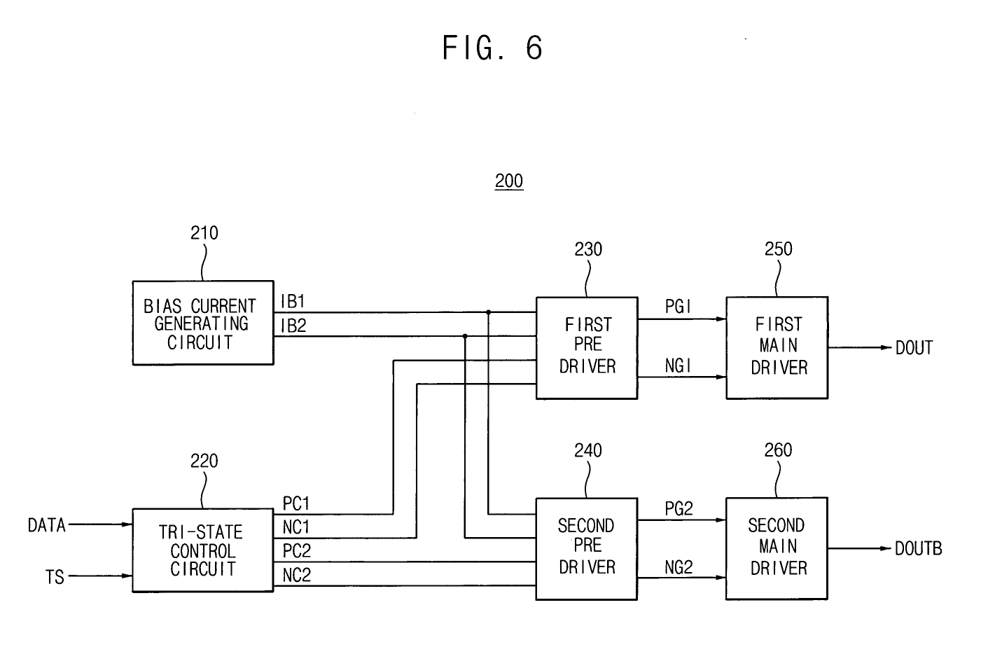

FIG. 6 is a block diagram of an output driver 200 of a semiconductor IC according to another embodiment of the present invention. The output driver 200 includes a bias current generating circuit 210, a tri-state control circuit 220, a first pre-driver 230, a second pre-driver 240, a first main driver 250, and a second main driver 260.

The bias current generating circuit 210 generates a first bias current IB1 and a second bias current IB2 that are provided to the first pre-driver 230 and the second pre-driver 240. The tri-state control circuit 220 generates a first input signal PC1, a second input signal NC1, a third input signal PC2, and a fourth input signal NC2 in response to a tri-state control signal TS and a data signal DATA.

The first pre-driver 230 buffers the first input signal PC1 to generate a first gate control signal PG1, and buffers the second input signal NC1 to generate a second gate control signal NG1. The second pre-driver 240 buffers the third input signal PC2 to generate a third gate control signal PG2, and buffers the fourth input signal NC2 to generate a fourth gate control signal NG2.

The first main driver 250 generates a first output signal DOUT in response to the first and second gate control signals PG1 and NG1. The second main driver 260 generates a second output signal DOUTB in response to the third and fourth gate control signals PG2 and NG2. The second output signal DOUTB is a complement (i.e., an inverse) of the first output signal DOUT, as illustrated in FIG. 8A.

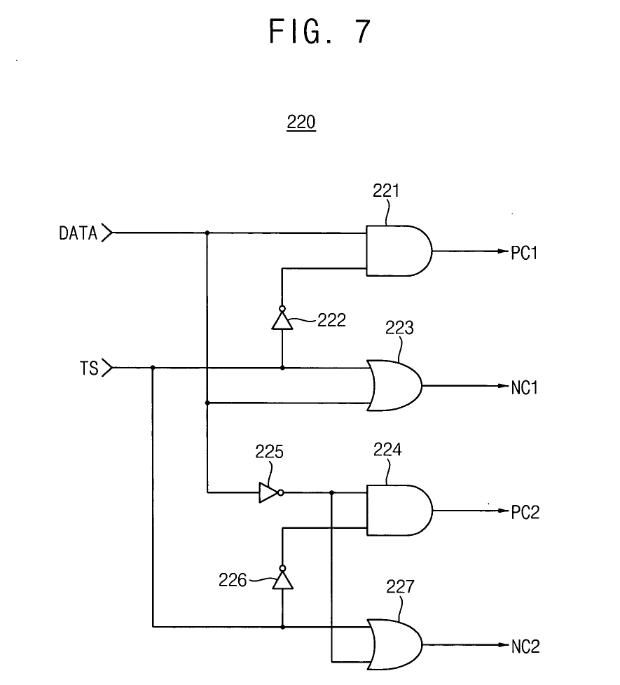

FIG. 7 is a circuit diagram of an example embodiment of the tri-state control circuit 220 of FIG. 6. The tri-state control circuit 220 includes AND gates 221 and 224, inverters 222, 225 and 226, and OR gates 223 and 227.

Referring to FIGS. 4 and 7, the inverter 222, the AND gate 221, and the OR gate 223 of FIG. 7 operate similarly to the inverter 122, the AND gate 121, and the OR gate 123 of FIG. 4. Thus, the AND gate 221 generates the first input signal PC1 and the OR gate 223 generates the second input signal NC1 in FIG. 7 similarly as already described with reference to FIG. 4.

The inverter 225 in FIG. 7 inverts the data signal DATA, and such an inverted data signal is input by the AND gate 224 and the OR gate 227. Otherwise, the inverter 226, the AND gate 224, and the OR gate 227 of FIG. 7 operate similarly to the inverter 122, the AND gate 121, and the OR gate 123 of FIG. 4. Thus, the AND gate 224 generates the third input signal PC2 that is an inversion of the first input signal PC1, and the OR gate 227 generates the fourth input signal NC2 that is an inversion of the second input signal NC1.

In addition, when the tri-state control signal TS is enabled to the logic high state, the first input signal PC1 is in a logic low state, and the second input signal NC1 is in a logic high state. With such logic states of the first and second input signals PC1 and NC1, the output node for having the first output signal DOUT generated thereon has a high impedance with the pull-up and pull-down transistors coupled to such an output node being turned off.

Similarly when the tri-state control signal TS is enabled to the logic high state, the third input signal PC2 is in a logic low state, and the fourth input signal NC2 is in a logic high state. With such logic states of the third and fourth input signals PC2 and NC2, the output node for having the second output signal DOUTB generated thereon has a high impedance with the pull-up and pull-down transistors coupled to such an output node being turned off.

When the tri-state control signal TS is disabled to the logic low state, the logic states of the first, second, third, and fourth input signals PC1, NC1, PC2, and NC2 are determined by the logic state of the data signal DATA. Generally in that case, the first and second input signals PC1 and NC1 are the same and are the logic state of the data signal DATA. Further in that case, the third and fourth inputs signals PC2 and NC2 are the same and are the inverse of the logic state of the data signal DATA.

Referring to FIGS. 5 and 6, each of the first pre-driver 230 and the second pre-driver 240 of FIG. 6 has substantially the same circuit topology as the pre-driver 130 of FIG. 5, in one embodiment of the present invention. In addition, each of the first main driver 250 and the second main driver 260 has substantially the same circuit topology as the main driver 140 of FIG. 5, in one embodiment of the present invention. Such an output driver 200 of FIG. 6 may be advantageously applied for use within a double data rate 2 (DDR2) dynamic random access memory (DRAM).

With such a circuit topology of the output driver 200, the first pre-driver 230 and the first main driver 250 have similar components and operation as the output driver 100 of FIG. 5. Thus, the reduced descending slope of the first gate control signal PG1 (as illustrated in FIG. 8A) results in a more constant slew rate of the output signal DOUT during a rising transition of the output signal DOUT in the output driver 200. Additionally, the reduced ascending slope of the second gate control signal NG1 (as illustrated in FIG. 8A) results in a more constant slew rate of the output signal DOUT during a falling transition of the output signal DOUT.

Furthermore, the second pre-driver 240 of FIG. 6 has substantially the same circuit topology as the pre-driver 130 of FIG. 5, and the second main driver 260 has substantially the same circuit topology as the main driver 140 of FIG. 5, in one embodiment of the present invention. Thus, the second pre-driver 240 of FIG. 6 is implemented with respective buffers, respective transmission gates, and a respective capacitor, similar to the pre-driver 130 of FIG. 5. In addition, the third and fourth gate control signal PG2 and NG2 are generated at third and fourth nodes, respectively, of the second pre-driver 240 similar to the first and second nodes N1 and N2, respectively, of the pre-driver 130 of FIG. 5. The second main driver 260 of FIG. 6 is implemented with respective pull-up and pull-down transistors, similar to the main driver 140 of FIG. 5.

The third and fourth input signals PC2 and NC2 are inversions of the first and second input signals PC1 and NC1 when the tri-state control signal TS is disabled to the logic low state. Thus, when the data signal DATA has a falling transition, the second output signal DOUTB has a rising transition. When the data signal DATA has a rising transition, the second output signal DOUTB has a falling transition.

For the rising transition of the second output signal DOUTB from a falling transition of the DATA signal, the third gate control signal PG2 is generated at the third node of the second pre-driver 240 with a reduced descending slope (similarly as illustrated for PG1 in FIG. 8A) resulting in a more constant slew rate of the second output signal DOUTB. Such a reduced descending slope results from a third capacitive current path being established from the other output node generating the second output signal DOUTB through a capacitor for the second pre-driver 240 (similar to the capacitor CF) to the third node.

For the falling transition of the second output signal DOUTB from a rising transition of the DATA signal, the fourth gate control signal NG2 is generated at the fourth node of the second pre-driver 240 with a reduced ascending slope (such as illustrated for NG1 in FIG. 8A) resulting in a more constant slew rate of the second output signal DOUTB. Such a reduced ascending slope results from a fourth capacitive current path being established from the fourth node through the capacitor for the second pre-driver 240 (similar to the capacitor CF) to the other output node generating the second output signal DOUTB.

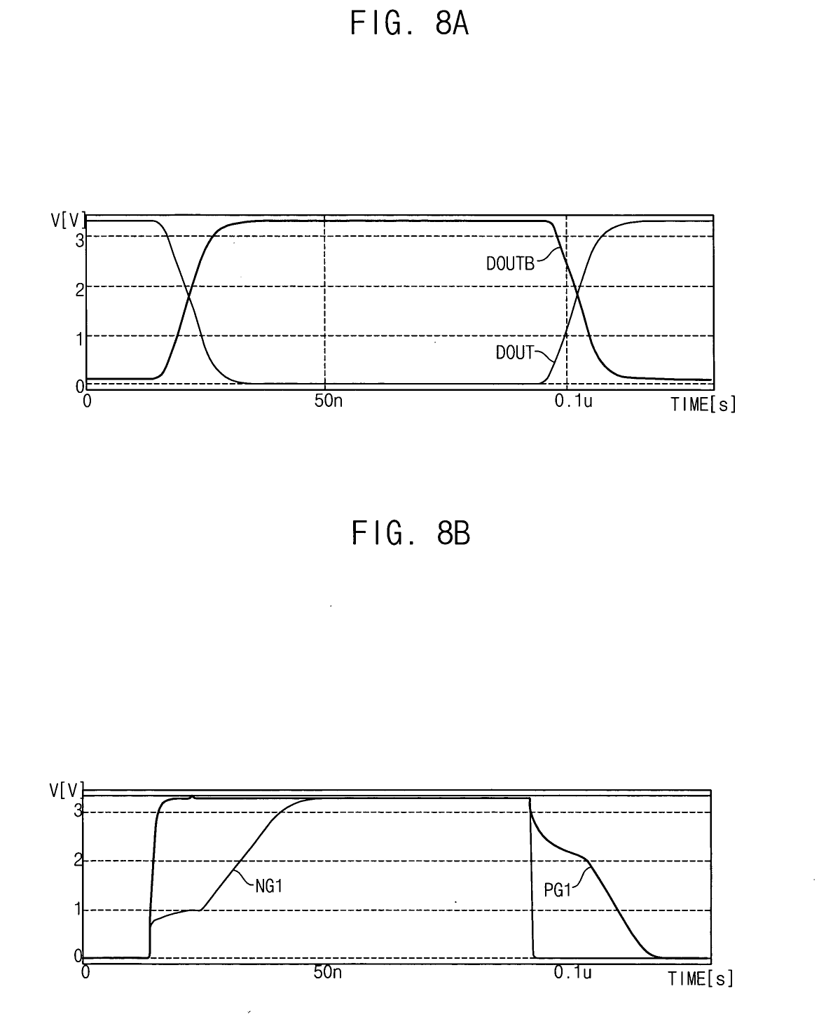

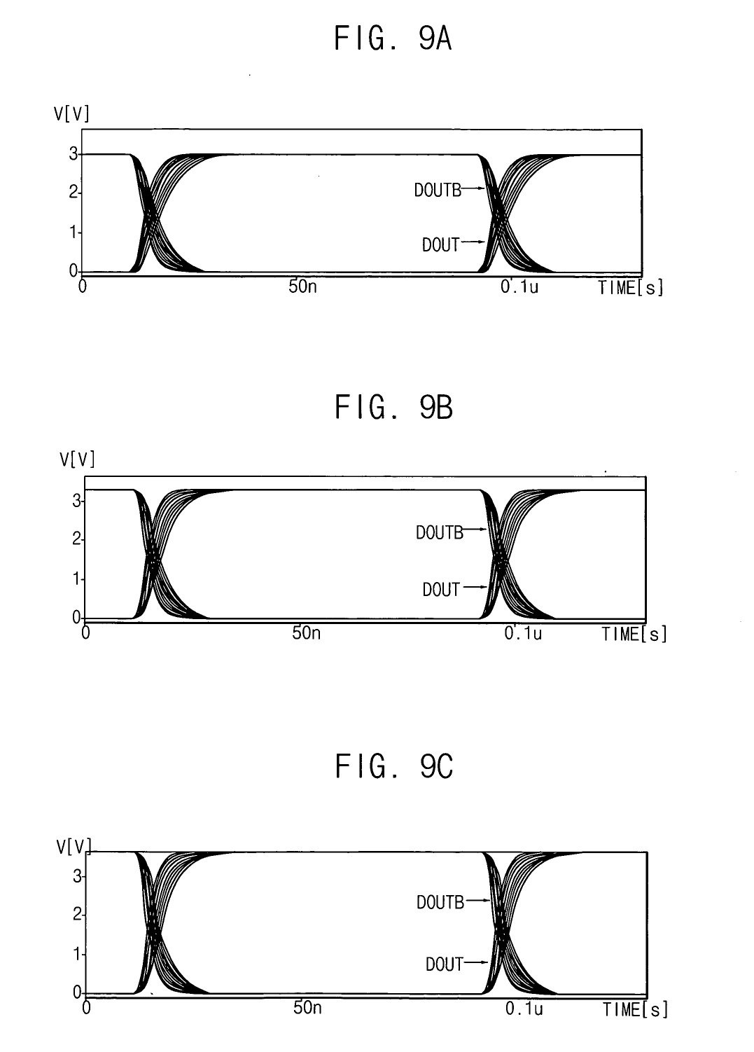

FIGS. 9A, 9B, and 9C are timing diagrams of the output signals for the conventional output driver of FIG. 1. FIG. 9A shows simulation results for the prior art output signals when VDD=3V, Temp={−55° C., 125° C.}, and Process={Fast, Typical, Slow}. FIG. 9B shows simulation results for the prior art output signals when VDD=3.3V, Temp={−55° C., 125° C.}, and Process={Fast, Typical, Slow}. FIG. 9C shows simulation results for the prior art output signals when VDD=3.6V, Temp={−55° C., 125° C.}, and Process={Fast, Typical, Slow}.

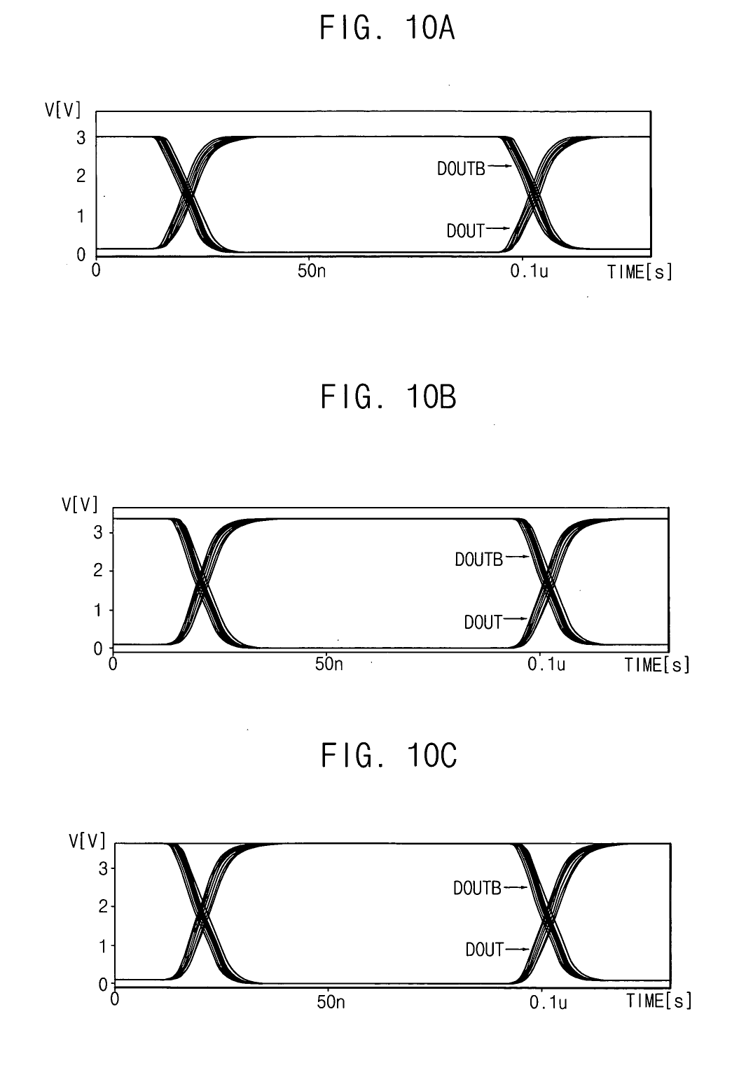

FIGS. 10A, 10B, and 10C are timing diagrams of the output signals DOUT and DOUTB for the output driver 200 of FIG. 6. FIG. 10A shows simulation results for such output signals when VDD=3V, Temp={−55° C., 125° C.}, and Process={Fast, Typical, Slow}. FIG. 10B shows simulation results for such output signals when VDD=3.3V, Temp={−55° C., 125° C.}, and Process={Fast, Typical, Slow}. FIG. 1C show simulation results for such output signals when VDD=3.6V, Temp={−55° C., 125° C.}, and Process={Fast, Typical, Slow}.

Comparing FIGS. 9A and 10A when VDD=3V, the output signals DOUT and DOUTB in FIG. 10A have a smaller range of fluctuations due to variations in temperature and process than the prior art output signals illustrated in FIG. 9A. Similarly when VDD=3.3V, the output signals DOUT and DOUTB in FIG. 10B have a smaller range of fluctuations due to variations in temperature and process than the prior art output signals illustrated in FIG. 9B.

Additionally when VDD=3.6V, the output signals DOUT and DOUTB in FIG. 10C have a smaller range of fluctuations due to variations in temperature and process than the prior art output signals illustrated in FIG. 9C. Furthermore, when VDD varies from 3V to 3.6V, the output signals DOUT and DOUTB in FIGS. 10A, 10B, and 10C have a smaller range of fluctuation than the prior art output signals in FIGS. 9A, 9B, and 9C.

Table 1 lists example ascending and descending times of output signals for the prior art output driver of FIG. 1 and the output driver 200 of FIG. 6:

TABLE 1

| | Prior Art | Present Invention |
|---|---|---|
| Ascending Time | 5.3 to 11.3 | 9.4 to 11.4 |
| Descending Time | 5.2 to 9.5 | 9.5 to 10.7 |
| Ratio of Change | About 113% | About 21% |

Referring to Table 1, with variation in process, voltage, and temperature, the range of variation of the output signals in the prior art output driver is about 113%. In contrast, the range of variation of the output signals of the output driver according to the present invention is about 21%, which is less than a fifth of the range of variation for the prior art output driver.

Thus, the output signals of the output driver 200 according to the present invention have a smaller variation of slew rate despite variations in process, voltage, and temperature. The output driver 200 according to the present invention advantageously maintains the slew rate of the output signals by forming capacitive current paths between the output node and the control gates of the pull-up and pull-down transistors.

Having thus described example embodiments of the present invention, it is to be understood that the invention defined by the appended claims is not to be limited by particular details set forth in the above description as many apparent variations thereof are possible without departing from the spirit or scope thereof as hereinafter claimed.

What is claimed is:

1. An output driver, comprising:
a pre-driver for generating first and second gate control signals at first and second nodes, respectively, from input signals; and
a main driver for generating an output signal at an output node from the first and second gate control signals;
wherein the pre-driver includes:
a capacitor coupled to the output node; and
switches, each turning on to form a respective capacitive current path between the output node through the capacitor and one of the first and second nodes during a transition of the output signal.

2. The output driver of claim 1, wherein the pre-driver includes:
a first switch that turns on to form a first capacitive current path from the output node through the capacitor to the first node during a rising transition of the output signal; and
a second switch that turns on to form a second capacitive current path from the second node through the capacitor to the output node during a falling transition of the output signal.

3. The output driver of claim 2, wherein the first capacitive current path reduces a descending slope of the first gate control signal during the rising transition of the output signal, and wherein the second capacitive current path reduces an ascending slope of the second gate control signal during the falling transition of the output signal.

4. The output driver of claim 2, further comprising:
a tri-state control circuit that generates first and second input signals each having a respective logic state such that the output node has a high impedance when a tri-state control signal is enabled.

5. The output driver of claim 4, wherein the tri-state control circuit is configured to generate the first and second input signals each having a logic state depending on a data signal when the tri-state control signal is disabled.

6. The output driver of claim 5, wherein the pre-driver includes:
a first buffer for buffering the first input signal to generate the first gate control signal at the first node; and
a second buffer for buffering the second input signal to generate the second gate control signal at the second node.

7. The output driver of claim 6, wherein each of the first and second buffers includes a respective inverter for inputting the first or second input signal and outputting the first or second gate control signal, and includes a respective current mirror for biasing the respective inverter.

8. The output driver of claim 5, wherein the first switch is a first transmission gate that is turned on by the first input signal to couple the capacitor to the first node during the rising transition of the output signal, and wherein the second switch is a second transmission gate that is turned on by the second input signal to couple the capacitor to the second node during the falling transition of the output signal.

9. The output driver of claim 1, further comprising:
another pre-driver for generating third and fourth gate control signals at third and fourth nodes, respectively, from inversions of the input signals; and
another main driver for generating another output signal at another output node from the third and fourth gate control signals, wherein the other output signal is a complement of the output signal;
and wherein the other pre-driver includes:
another capacitor coupled to the other output node; and
additional switches, each turning on to form a respective capacitive current path between the other output node through the other capacitor and one of the third and fourth nodes during a transition of the other output signal.

10. The output driver of claim 9, wherein the other pre-driver includes:
a third switch that turns on to form a third capacitive current path from the other output node through the other capacitor to the third node during a rising transition of the other output signal; and
a fourth switch that turns on to form a fourth capacitive current path from the fourth node through the other capacitor to the other output node during a falling transition of the other output signal.

11. The output driver of claim 10, wherein the third capacitive current path reduces a descending slope of the third gate control signal during the rising transition of the other output signal, and wherein the fourth capacitive current path reduces an ascending slope of the fourth gate control signal during the falling transition of the other output signal.

12. The output driver of claim 9, further comprising:
a tri-state control circuit that generates first, second, third, and fourth input signals each having a respective logic state such that the output node and the other output node each have a high impedance when a tri-state control signal is enabled, and wherein the tri-state control circuit is configured to generate the first, second, third, and fourth input signals each have a respective logic state depending on a data signal when the tri-state control signal is disabled.

13. An output driver, comprising:
a pre-driver for generating first and second gate control signals at first and second nodes, respectively, from input signals; and
a main driver for generating an output signal at an output node from the first and second gate control signals;
wherein the pre-driver includes:
means for reducing a descending slope of the first gate control signal during a rising transition of the output signal, and for reducing an ascending slope of the second gate control signal during a falling transition of the output signal.

14. The output driver of claim 13, further comprising:
means for generating first and second input signals each having a respective logic state such that the output node has a high impedance when a tri-state control signal is enabled.

15. The output driver of claim 14, further comprising:
means for generating the first and second input signals each have a logic state depending on a data signal when the tri-state control signal is disabled.

16. The output driver of claim 13, further comprising:
another pre-driver for generating third and fourth gate control signals at third and fourth nodes, respectively, from inversions of the input signals; and
another main driver for generating another output signal at another output node from the third and fourth gate control signals, wherein the other output signal is a complement of the output signal;
and wherein the other pre-driver includes:
means for reducing a descending slope of the third gate control signal during a rising transition of the other output signal, and for reducing an ascending slope of the fourth gate control signal during a falling transition of the other output signal.

17. A method of driving an output driver, comprising:
generating first and second gate control signals at first and second nodes, respectively, from input signals;
generating an output signal at an output node from the first and second gate control signals;
forming a first capacitive current path from the output node to the first node to reduce a descending slope of the first gate control signal during a rising transition of the output signal; and
forming a second capacitive current path from the second node to the output node to reduce an ascending slope of the second gate control signal during a falling transition of the output signal.

18. The method of claim 17, further comprising:
generating first and second input signals each having a respective logic state such that the output node has a high impedance when a tri-state control signal is enabled.

19. The method of claim 18, further comprising:
generating the first and second input signals each have a logic state depending on a data signal when the tri-state control signal is disabled.

20. The method of claim 17, further comprising:
generating third and fourth gate control signals at third and fourth nodes, respectively, from inversions of the input signals;
generating another output signal at another output node from the third and fourth gate control signals, wherein the other output signal is a complement of the output signal;
forming a third capacitive current path from the other output node to the third node to reduce a descending slope of the third gate control signal during a rising transition of the other output signal; and
forming a fourth capacitive current path from the fourth node to the other output node to reduce an ascending slope of the fourth gate control signal during a falling transition of the other output signal.
